(19) United States
(12) Patent Application Publication
(10) Pub. No.: US 2025/0311517 A1
(43) Pub. Date: Oct. 2, 2025

(54) LIGHT EMITTING ELEMENT

(71) Applicant: NICHIA CORPORATION, Anan-shi (JP)

(72) Inventors: Eiji MURAMOTO, Tokushima-shi (JP); Ryohei KOBAYASHI, Tokushima-shi (JP); Kosuke YOSHIOKA, Naruto-shi (JP)

(73) Assignee: NICHIA CORPORATION, Anan-shi (JP)

(21) Appl. No.: 19/081,423

(22) Filed: Mar. 17, 2025

(30) Foreign Application Priority Data
Mar. 28, 2024 (JP) 2024-052975

(51) Int. Cl. H10H 29/85; H01L 25/075

(52) U.S. Cl. CPC H10H 29/857; H01L 25/0753

(57) ABSTRACT

A light-emitting element includes: a substrate; a conductive member disposed on the substrate; a first insulating layer disposed on the conductive member; a semiconductor structure including a first light-emitting unit and a second light-emitting unit that are spaced apart from each other on the first insulating layer; a first wiring electrically connected to a first semiconductor layer of the first light-emitting unit; a second wiring electrically connected to a second semiconductor layer of the first light-emitting unit and the first semiconductor layer of the second light-emitting unit; a third wiring electrically connected to the second semiconductor layer of the second light-emitting unit; a first pad electrode separated from the semiconductor structure in a plan view and electrically connected to the first wiring; and a second pad electrode separated from the semiconductor structure in a plan view and electrically connected to the third wiring.

### CROSS-REFERENCE TO RELATED APPLICATIONS

This application is based on and claims priority to Japanese Patent Application No. 2024-052975, filed on Mar. 28, 2024, the entire contents of which are incorporated herein by reference.

### FIELD

The present disclosure relates to a light-emitting element.

### BACKGROUND

Japanese Patent Publication No. 2015-533022 and Japanese Patent Publication No. 2021-34652 disclose a light-emitting element has been proposed in which two active regions connected in series to each other are provided on one substrate.

### SUMMARY

In a conventional light-emitting element, it is necessary to reduce a forward voltage.

An object of the present disclosure is to provide a light-emitting element that can reduce a forward voltage.

According to an aspect the technology of the present disclosure, a light-emitting element includes a substrate; a conductive member disposed on the substrate; a first insulating layer disposed on the conductive member; a semiconductor structure including a first light-emitting unit and a second light-emitting unit that are spaced apart from each other on the first insulating layer, each of the first light-emitting unit and the second light-emitting unit including a first semiconductor layer of a first conductivity type, a second semiconductor layer of a second conductivity type, and a light-emitting layer disposed between the first semiconductor layer and the second semiconductor layer; a first wiring electrically connected to the first semiconductor layer of the first light-emitting unit; a second wiring electrically connected to the second semiconductor layer of the first light-emitting unit and the first semiconductor layer of the second light-emitting unit; a third wiring electrically connected to the second semiconductor layer of the second light-emitting unit; a first pad electrode separated from the semiconductor structure in a plan view and electrically connected to the first wiring; and a second pad electrode separated from the semiconductor structure in a plan view and electrically connected to the third wiring, in which the first insulating layer is provided with one or more first openings, the first wiring is in contact with the conductive member through the one or more first openings, and the second wiring and the third wiring are not in contact with the conductive member.

According to the present disclosure, a light-emitting element that can reduce a forward voltage can be provided.

### BRIEF DESCRIPTION OF DRAWINGS

FIG. 1 is a top view illustrating some of components of a light-emitting element according to a first embodiment.

FIG. 2 is an exploded top view illustrating some of components of the light-emitting element according to the first embodiment.

FIG. 3 is a cross-sectional view illustrating the light-emitting element according to the first embodiment.

FIG. 4 is a top view illustrating some of components of a light-emitting element according to a second embodiment.

FIG. 5 is an exploded top view illustrating some of components of the light-emitting element according to the second embodiment.

FIG. 6 is a cross-sectional view illustrating the light-emitting element according to the second embodiment.

FIG. 7 is a top view illustrating some of components of a light-emitting element according to a third embodiment.

FIG. 8 is a top view illustrating some of components of a light-emitting element according to a fourth embodiment.

FIG. 9 is an exploded top view illustrating some of components of the light-emitting element according to the fourth embodiment.

FIG. 10 is a cross-sectional view illustrating the light-emitting element according to the fourth embodiment.

FIG. 11 is a top view illustrating some of components of a light-emitting element according to a fifth embodiment.

FIG. 12 is a top view illustrating a modified example of arrangement of an n-type semiconductor layer and a pad electrode.

### DETAILED DESCRIPTION

Hereinafter, embodiments for carrying out the present disclosure are described with reference to the drawings. The following description is intended to embody technical concepts of the present disclosure, and but present invention is not limited to the described embodiments unless specifically stated.

In each drawing, members having identical functions may be denoted by the same reference characters. In view of the ease of explanation or understanding of the points, the embodiment may be illustrated separately for convenience, but the partial substitutions or combinations of the configurations illustrated in different embodiments and examples are possible. In the embodiments described later, differences from the embodiment described earlier will be mainly described, and redundant descriptions of commonalities with the embodiment described earlier are sometimes omitted. The size, positional relationship, and other features of members illustrated in the drawings may be exaggerated to clarify explanation. To avoid excessive complication of the drawings, in some cases, some elements are not illustrated, or an end view illustrating only a cut surface is used as a cross-sectional view. While an XYZ orthogonal coordinate system is used in the following description, the coordinate system is defined for the purpose of description and does not limit the orientation of a substrate or the like. In addition, when viewed from an arbitrary point, a +Z side is sometimes referred to as upper, an upper side, or above, and a −Z side may be referred to as lower, a lower side, or below. Viewing in a direction along a Z direction is referred to as a “plan view.”

### First Embodiment

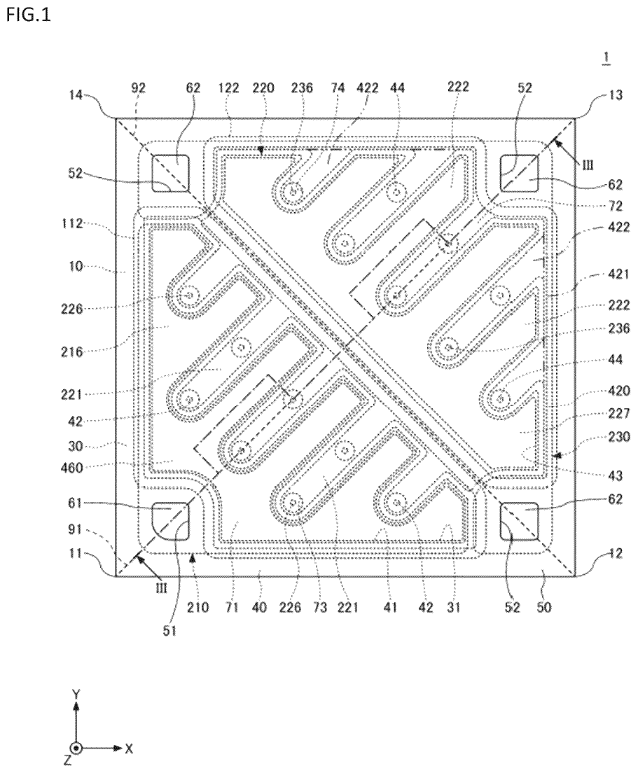

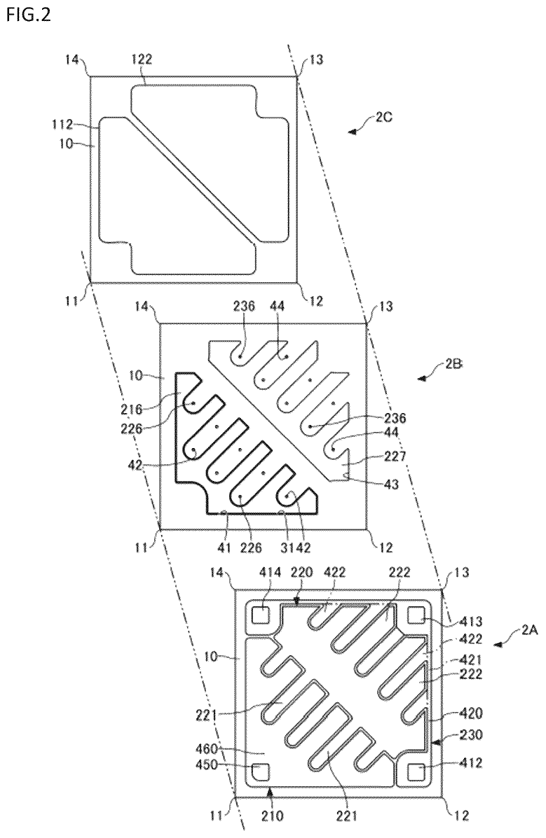

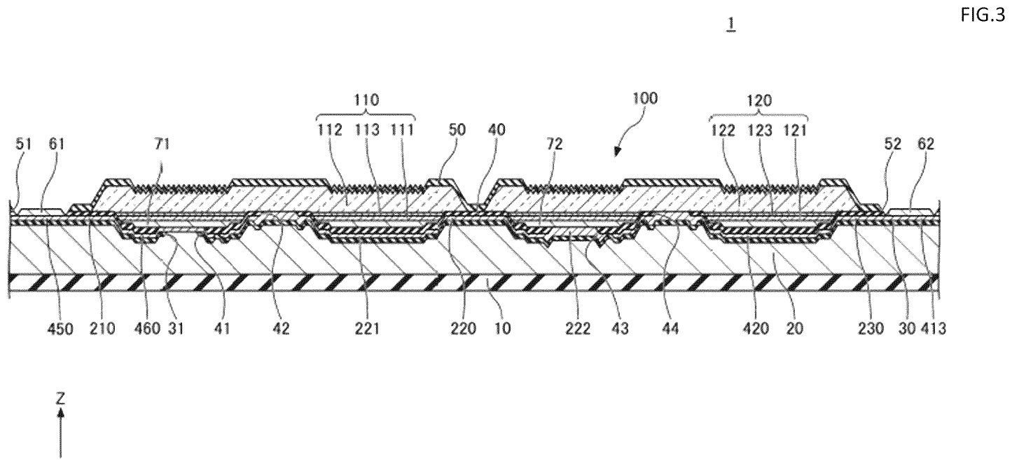

A light-emitting element according to a first embodiment will now be described. FIG. 1 is a top view illustrating some of components of the light-emitting element according to the first embodiment. FIG. 2 is an exploded top view illustrating some of components of the light-emitting element according to the first embodiment. FIG. 3 is a cross-sectional view illustrating the light-emitting element according to the first embodiment. FIG. 3 corresponds to a cross-sectional view taken along line III-III in FIG. 1.

A light-emitting element 1 according to the first embodiment includes a substrate 10, a conductive member 20, a first insulating layer 30, a second insulating layer 40, a third insulating layer 50, a first pad electrode 61, second pad electrodes 62, light reflecting conductive layers 71 and 72, a semiconductor structure 100, a first wiring 210, a second wiring 220, and a third wiring 230.

The substrate 10 is, for example, an insulating substrate. The substrate 10 may be a semiconductor substrate or a conductive substrate. A shape of the substrate 10 in a plan view is square. When the shape of the substrate 10 in a plan view is square, the length of a side of the substrate 10 is, for example, in a range from 500 μm to 3000 μm. In a plan view, the substrate 10 has vertexes 11, 12, 13, and 14. The vertex 11 is a vertex on the −X side and the −Y side with respect to the center of the substrate 10 as a starting point. The vertex 12 is a vertex on the +X side and the −Y side with respect to the center of the substrate 10 as a starting point. The vertex 13 is a vertex on the +X side and the +Y side with respect to the center of the substrate 10 as a starting point. The vertex 14 is a vertex on the −X side and the +Y side with respect to the center of the substrate 10 as a starting point. As the substrate 10, for example, a silicon substrate can be used. A thickness of the substrate 10 is, for example, in a range from 100 μm to 1000 μm.

In a layer 2A in FIG. 2, the arrangement of the first wiring 210, the second wiring 220, and the third wiring 230 is illustrated with respect to the substrate 10. In a layer 2B in FIG. 2, the arrangement of an opening 31 included in the first insulating layer 30, the arrangement of openings 41, 42, 43, and 44 included in the second insulating layer 40, and the arrangement of regions 216, 226, 227, and 236 in the openings 41, 42, 43, and 44 of the first wiring 210, the second wiring 220, and the third wiring 230 are illustrated with respect to the substrate 10. In a layer 2C in FIG. 2, the arrangement of n-type semiconductor layers 112 and 122 included in the semiconductor structure 100 is illustrated with respect to the substrate 10. The two types of vertexes, the vertexes 11 and the vertexes 13, of the substrate 10 are indicated in a manner that the vertexes 11 are connected to each other and the vertexes 13 are connected to each other, between the layers 2A, 2B, and 2C, by respective two-dot chain lines.

As illustrated in FIG. 3, the conductive member 20 is disposed on the substrate 10. The conductive member 20 includes a metal layer of solder or the like. A thickness of the conductive member 20 is, for example, in a range from 3 μm to 10 μm. The first insulating layer 30 is disposed on the conductive member 20. The first insulating layer 30 is a layer containing at least one of silicon oxide, silicon nitride, and silicon oxynitride, for example. The first wiring 210, the second wiring 220, and the third wiring 230 are disposed on the first insulating layer 30. A thickness of the first insulating layer 30 is, for example, in a range from 0.1 μm to 2 μm.

As illustrated in FIGS. 1 and 2, in a plan view, the first wiring 210 is disposed inside a triangle having the vertexes 11, 12, and 14 as three vertexes. The first wiring 210 includes a connection portion 450 and an extending portion 460. The connection portion 450 is disposed in the vicinity of the vertex 11. The extending portion 460 is connected to the connection portion 450 and extends from the connection portion 450. The first pad electrode 61 is connected to the connection portion 450. The outer shape of the extending portion 460 in a plan view includes a portion parallel to a side connecting the vertexes 11 and 12 to each other, a portion parallel to a diagonal line 92 connecting the vertexes 12 and 14 to each other, and a portion parallel to a side connecting the vertexes 14 and 11 to each other. In a plan view, the extending portion 460 includes a plurality of portions each extending in a direction parallel to a diagonal line 91 connecting the vertexes 11 and 13 to each other. In a plan view, a part of the second wiring 220 is located between a plurality of portions of the extending portion 460. In a direction parallel to the diagonal line 92, a part of the first wiring 210 and an extending portion 221 of the second wiring 220 described later are alternately disposed.

As illustrated in FIGS. 1 and 2, the third wiring 230 includes connection portions 412, 413, and 414 and an extending portion 420. The connection portion 412 is disposed in the vicinity of the vertex 12, the connection portion 413 is disposed in the vicinity of the vertex 13, and the connection portion 414 is disposed in the vicinity of the vertex 14. The extending portion 420 is connected to the connection portions 412, 413, and 414 and extends from the connection portions 412, 413, and 414. The second pad electrode 62 is connected to each of the connection portions 412, 413, and 414. The extending portion 420 includes a first extending portion 421 and a plurality of second extending portions 422. In a plan view, the first extending portion 421 extends from the connection portions 412 and 413 in a direction parallel to the outer edge of the semiconductor structure 100. Apart of the first extending portion 421 extends in a direction parallel to the outer edge of the semiconductor structure 100, between the connection portion 412 and the connection portion 413, and another part of the first extending portion 421 extends in a direction parallel to the outer edge of the semiconductor structure 100, between the connection portion 413 and the connection portion 414. The second extending portion 422 extends from the first extending portion 421 in the direction parallel to the diagonal line 91. In the direction parallel to the diagonal line 92, the second extending portion 422 and an extending portion 222 of the second wiring 220 to be described later are alternately arranged. For example, a width of the second extending portion 422 is greater than a width of the first extending portion 421. The width of the second extending portion 422 is the length of the second extending portion 422 in a direction orthogonal to the direction in which the second extending portion 422 extends. In FIG. 1, the width of the second extending portion 422 is a width in the direction parallel to the diagonal line 92. The width of the first extending portion 421 in a plan view is, for example, in a range from 5 μm to 100 μm. The width of the second extending portion 422 in a plan view is, for example, in a range from 10 μm to 300 μm.

As illustrated in FIGS. 1 and 2, the second wiring 220 is disposed between the first wiring 210 and the third wiring 230 in the direction parallel to the diagonal line 91. The second wiring 220 includes a plurality of the extending portions 221 located in corresponding recessed portions of the first wiring 210 and a plurality of the extending portions 222 each located between corresponding ones of the second extending portions 422 of the third wiring 230.

The material of the first wiring 210, the second wiring 220, and the third wiring 230 is a metal. As the material of the first wiring 210, the second wiring 220, and the third wiring 230, for example, a single-component metal such as Ag, Al, Ni, Rh, Au, Cu, Ti, Pt, Pd, Mo, Cr, W, or Ru or an alloy containing any of these metals as a main component can be suitably used. The material of the first wiring 210, the second wiring 220, and the third wiring 230 is, for example, an Al alloy. Each of the first wiring 210, the second wiring 220, and the third wiring 230 may have a single-layer structure composed of one layer of layers made of these metals, or a layered structure in which a plurality of the layers are layered. A thickness of each of the first wiring 210, the second wiring 220, and the third wiring 230 is, for example, in a range from 0.3 μm to 3 μm.

As illustrated in FIG. 3, the second insulating layer 40 is disposed over the first insulating layer 30 so as to cover the first wiring 210, the second wiring 220, and the third wiring 230. The second insulating layer 40 is a layer containing at least one of silicon oxide, silicon nitride, silicon oxynitride, and aluminum oxide. The second insulating layer 40 includes one opening 41 as a second opening, a plurality of the openings 42, one opening 43, and a plurality of the openings 44. The openings 41, 42, 43, and 44 penetrate through the second insulating layer 40. A thickness of the second insulating layer 40 is, for example, in a range from 0.1 μm to 2 μm.

As illustrated in FIGS. 1 and 2, the outer shape of the opening 41 is smaller than the outer shape of the first wiring 210 in a plan view. The opening 41 is located inside the outer edge of the first wiring 210 in a plan view. A shape of the opening 42 in a plan view is circular. When the shape of the opening 42 in a plan view is circular, a diameter of the opening 42 is in a range from 2 μm to 20 μm. The opening 42 is located inside the outer edge of the extending portion 221 of the second wiring 220 in a plan view. The outer shape of the opening 43 is smaller than the outer shape of the second wiring 220 in a plan view. The opening 43 is located inside the outer edge of the second wiring 220 in a plan view. A shape of the opening 44 in a plan view is circular. When the shape of the opening 44 in a plan view is circular, a diameter of the opening 44 is in a range from 2 μm to 20 μm. The opening 44 is located inside the outer edge of the second extending portion 422 of the third wiring 230 in a plan view. The second insulating layer 40 may include a plurality of the openings 41, may include a plurality of the openings 43, and may include one opening 44.

In a plan view, the first wiring 210 includes the region 216 disposed inside the opening 41. In a plan view, the second wiring 220 includes the region 226 disposed inside the opening 42 and the region 227 disposed inside the opening 43. In a plan view, the third wiring 230 includes a region 236 disposed inside the opening 44.

As illustrated in FIGS. 1 and 3, in a cross-sectional view, the light reflecting conductive layer 71 is disposed on the second insulating layer 40 so as to be separated from the opening 42 and overlap the extending portion 460 of the first wiring 210 and the extending portion 221 of the second wiring 220. The light reflecting conductive layer 71 is electrically connected to the first wiring 210 through the opening 41. In a plan view, the light reflecting conductive layer 71 includes a plurality of openings 73. A shape of the opening 73 of the light reflecting conductive layer 71 in a plan view is circular. In a plan view, the opening 42 is located inside the opening 73 of the light reflecting conductive layer 71. In a plan view, the light reflecting conductive layer 72 is disposed on the second insulating layer 40 so as to be separated from the opening 44 and overlap a portion (including the extending portion 222) of the second wiring 220 closer to the vertex 13 relative to the diagonal line 92 and the extending portion 420 of the third wiring 230. The light reflecting conductive layer 72 is electrically connected to the second wiring 220 through the opening 43. In a plan view, the light reflecting conductive layer 72 includes a plurality of openings 74. A shape of the opening 74 of the light reflecting conductive layer 72 in a plan view is circular. In a plan view, the opening 44 is located inside the opening 74 of the light reflecting conductive layer 72. The material of the light reflecting conductive layers 71 and 72 is a metal. For example, a single-component metal such as Ag, Al, Ni, Ti, Pt, Ta, Ru, Rh, or Au or an alloy containing any of these metals as a main component can be suitably used for the light reflecting conductive layers 71 and 72. Each of the light reflecting conductive layers 71 and 72 may have a single-layer structure composed of one layer of layers made of these metals, or a layered structure in which a plurality of the layers are layered. A thickness of the light reflecting conductive layer 71 is, for example, in a range from 0.05 μm to 1 μm.

As illustrated in FIG. 3, the semiconductor structure 100 is disposed on the second insulating layer 40 and the light reflecting conductive layers 71 and 72. The semiconductor structure 100 includes a first light-emitting unit 110 and a second light-emitting unit 120. As illustrated in FIGS. 1 and 2, a shape of each of the first light-emitting unit 110 and the second light-emitting unit 120 in a plan view is substantially triangular. The first light-emitting unit 110 is disposed on the vertex 11 side with respect to the diagonal line 92, and the second light-emitting unit 120 is disposed on the vertex 13 side with respect to the diagonal line 92. A thickness of the semiconductor structure 100 is, for example, in a range from 1 μm to 10 μm.

The first light-emitting unit 110 includes a p-type semiconductor layer 111 as a first semiconductor layer, an n-type semiconductor layer 112 as a second semiconductor layer, and a light-emitting layer 113. The light-emitting layer 113 is disposed between the p-type semiconductor layer 111 and the n-type semiconductor layer 112. The p-type semiconductor layer 111 is disposed on the light reflecting conductive layer 71 and the second insulating layer 40 so as to be separated from the opening 42 in a plan view, and the light-emitting layer 113 is disposed on the p-type semiconductor layer 111. The light reflecting conductive layer 71 and the p-type semiconductor layer 111 are electrically connected to each other. The n-type semiconductor layer 112 is disposed on the region 226 of the second wiring 220, the light-emitting layer 113, and the second insulating layer 40. As illustrated in FIGS. 1 and 2, a shape of the n-type semiconductor layer 112 in a plan view is substantially triangular. An upper surface of the n-type semiconductor layer 112 located on a side opposite to the light-emitting layer 113 includes a plurality of protrusions. The protrusions of the n-type semiconductor layer 112 are disposed in a portion overlapping the light-emitting layer 113 in a plan view. A shape of the protrusions of the n-type semiconductor layer 112 is, for example, a conical shape, a polygonal pyramid shape, or a truncated cone shape.

The second light-emitting unit 120 includes a p-type semiconductor layer 121 as a first semiconductor layer, an n-type semiconductor layer 122 as a second semiconductor layer, and a light-emitting layer 123. The light-emitting layer 123 is disposed between the p-type semiconductor layer 121 and the n-type semiconductor layer 122. The p-type semiconductor layer 121 is disposed on the light reflecting conductive layer 72 and the second insulating layer 40 so as to be separated from the opening 44 in a plan view, and the light-emitting layer 123 is disposed on the p-type semiconductor layer 121. The light reflecting conductive layer 72 and the p-type semiconductor layer 121 are electrically connected to each other. The n-type semiconductor layer 122 is disposed on the region 236 of the third wiring 230, the light-emitting layer 123, and the second insulating layer 40. As illustrated in FIGS. 1 and 2, a shape of the n-type semiconductor layer 122 in a plan view is substantially triangular. An upper surface of the n-type semiconductor layer 122 located on a side opposite to the light-emitting layer 123 includes a plurality of protrusions. The protrusions of the n-type semiconductor layer 122 are disposed in a portion overlapping the light-emitting layer 123 in a plan view. A shape of the protrusions of the n-type semiconductor layer 122 in a cross-sectional view is, for example, a conical shape, a polygonal pyramid shape, or a truncated cone shape.

The first light-emitting unit 110 and the second light-emitting unit 120 are spaced apart from each other. The first light-emitting unit 110 and the second light-emitting unit 120 are electrically connected to each other by conductive members such as the first wiring 210, the second wiring 220, and the third wiring 230.

As the material of the p-type semiconductor layers 111 and 121, the material of the n-type semiconductor layers 112 and 122, and the material of the light-emitting layers 113 and 123, for example, a nitride semiconductor can be used. It is assumed that the “nitride semiconductor” includes, in its category, semiconductors having all compositions of a chemical formula expressed by InₓAl_{y}Ga_{1-x-y}N (0≤x, 0≤y, x+y<1) in which the composition ratios of x and y are changed within the respective ranges. It is assumed that the “nitride semiconductor” includes, in its category, a semiconductor further containing a group V element other than nitrogen (N), and a semiconductor further containing any of various elements added to control any of various physical properties such as a conductivity type, in the above chemical formula. Each of the p-type semiconductor layers 111 and 121, the n-type semiconductor layers 112 and 122, and the light-emitting layers 113 and 123 may have a single-layer structure or a layered structure including a plurality of semiconductor layers each having different compositions, thicknesses, and the like. In particular, each of the light-emitting layers 113 and 123 is preferably a single quantum well structure or a multiple quantum well structure in which thin semiconductor layers exhibiting a quantum effect are layered. The n-type semiconductor layers 112 and 122 each include a semiconductor layer containing an n-type impurity. Si, Ge, or the like is used as the n-type impurity. The p-type semiconductor layers 111 and 121 each include a semiconductor layer containing a p-type impurity. Mg, Zn, or the like is used as the p-type impurity. A peak wavelength of light emitted by the light-emitting layer 113 is the same as a peak wavelength of light emitted by the light-emitting layer 123. The peak wavelength of the light emitted by the light-emitting layer 113 and the light emitted by the light-emitting layer 123 is, for example, in a range from 210 nm to 580 nm. The peak wavelength of the light emitted by the light-emitting layer 113 may be different from the peak wavelength of the light emitted by the light-emitting layer 123.

The first wiring 210 is electrically connected to the p-type semiconductor layer 111 of the first light-emitting unit 110 through the opening 41. The second wiring 220 is electrically connected to the n-type semiconductor layer 112 of the first light-emitting unit 110 through the opening 42, and is electrically connected to the p-type semiconductor layer 121 of the second light-emitting unit 120 through the opening 43. The third wiring 230 is electrically connected to the n-type semiconductor layer 122 of the second light-emitting unit 120 through the opening 44.

As illustrated in FIG. 3, the third insulating layer 50 is disposed covering the semiconductor structure 100 and the second insulating layer 40. The third insulating layer 50 is a layer containing at least one of silicon oxide, silicon nitride, aluminum oxide, and silicon oxynitride. Of an upper surface of the third insulating layer 50, respective upper surfaces overlapping the n-type semiconductor layers 112 and 122 have respective shapes reflecting shapes of the protrusions on the upper surfaces of the n-type semiconductor layers 112 and 122 in a cross-sectional view. A layered body of the second insulating layer 40 and the third insulating layer 50 includes openings 51 and 52. The openings 51 and 52 penetrate through the layered body of the second insulating layer 40 and the third insulating layer 50. The opening 51 reaches the connection portion 450 of the first wiring 210, and the opening 52 reaches the connection portions 412, 413, and 414 of the third wiring 230. A thickness of the third insulating layer 50 is, for example, in a range from 0.01 μm to 2 μm.

The first pad electrode 61 is disposed on the connection portion 450 inside the opening portion 51. The first pad electrode 61 is electrically connected to the connection portion 450. That is, the first pad electrode 61 is separated from the semiconductor structure 100 in a plan view and is electrically connected to the first wiring 210. The second pad electrode 62 is disposed on the connection portions 412, 413, and 414 inside the opening 52. The second pad electrode 62 is electrically connected to the connection portions 412, 413, and 414. That is, the second pad electrode 62 is separated from the semiconductor structure 100 in a plan view and is electrically connected to the third wiring 230. As illustrated in FIG. 3, the first insulating layer 30 is disposed between the connection portion 450 and the conductive member 20, and is also disposed between the connection portion 413 and the conductive member 20. That is, the first insulating layer 30 is disposed between the first pad electrode 61 and the conductive member 20 and between the second pad electrode 62 and the conductive member 20. Although not illustrated, the first insulating layer 30 is also disposed between each of the connection portions 412 and 414 and the conductive member 20.

As illustrated in FIGS. 1 to 3, the first insulating layer 30 includes the opening 31 as a first opening. The opening 31 penetrates through the first insulating layer 30. The opening 31 is located inside the opening 41 in a plan view and overlaps at least the opening 41 in a plan view. A part of the conductive member 20 is disposed inside the opening 31, and the first wiring 210 is in contact with the conductive member 20. That is, the first wiring 210 is electrically connected to the conductive member 20 through the opening 31. On the other hand, the second wiring 220 and the third wiring 230 are not in contact with the conductive member 20. The first insulating layer 30 may include a plurality of the openings 31.

In the first embodiment, the first wiring 210 is electrically connected to the conductive member 20 through the opening 31. Thus, a sheet resistance between the first pad electrode 61 and the p-type semiconductor layer 111 can be reduced, and the forward voltage can be reduced as compared with a case in which the first wiring 210 is not electrically connected to the conductive member 20 through the opening 31. In addition, heat generated in the semiconductor structure 100 is easily transmitted to the conductive member 20, and heat dissipation properties can be improved as compared with a case in which the first insulating layer 30 does not include the opening 31.

In particular, because the opening 31 overlaps the opening 41 in a plan view, a sheet resistance in the vicinity of the region 216, of the first wiring 210, functioning as a contact region with respect to the p-type semiconductor layer 111 is easily reduced.

In a plan view, an area of the opening 31 is preferably in a range from 10% to 50% of an area of the first light-emitting unit 110. When the area of the opening 31 is 10% or more of the area of the first light-emitting unit 110, a sheet resistance of the first wiring 210 is easily reduced. On the other hand, when the area of the opening 31 is 50% or less of the area of the first light-emitting unit 110, the area in which the second wiring 220 can be disposed is easily increased.

### Second Embodiment

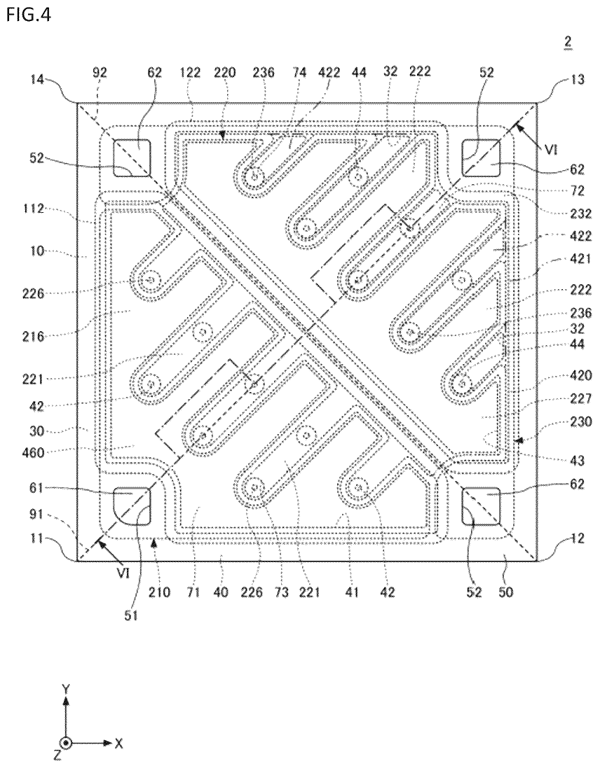

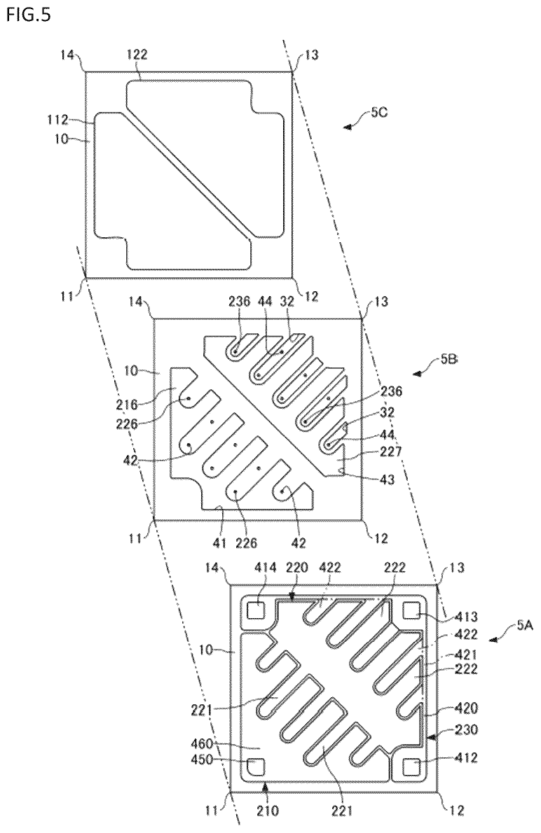

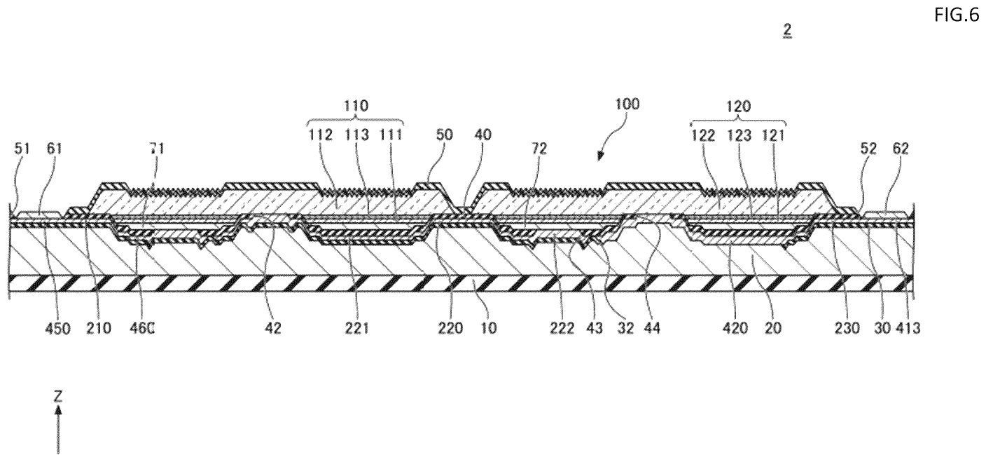

Next, a light-emitting element according to a second embodiment will be described. The second embodiment differs from the first embodiment mainly in a configuration of the first insulating layer 30. FIG. 4 is a top view illustrating some of components of the light-emitting element according to the second embodiment. FIG. 5 is an exploded top view illustrating some of components of the light-emitting element according to the second embodiment. FIG. 6 is a cross-sectional view illustrating the light-emitting element according to the second embodiment. FIG. 6 corresponds to a cross-sectional view taken along line VI-VI in FIG. 4.

In a layer 5A in FIG. 5, the arrangement of the first wiring 210, the second wiring 220, and the third wiring 230 is illustrated with respect to the substrate 10. In a layer 5B in FIG. 5, the arrangement of an opening 32 included in the first insulating layer 30, the arrangement of openings 41, 42, 43, and 44 included in the second insulating layer 40, and the arrangement of regions 216, 226, 227, and 236 in the openings 41, 42, 43, and 44 of the first wiring 210, the second wiring 220, and the third wiring 230 are illustrated with respect to the substrate 10. In a layer 5C in FIG. 5 the arrangement of the n-type semiconductor layers 112 and 122 is illustrated with respect to the substrate 10. The two types of vertexes, the vertexes 11 and the vertexes 13, of the substrate 10 are indicated in a manner that the vertexes 11 are connected to each other and the vertexes 13 are connected to each other, between the layers 5A, 5B, and 5C, by respective two-dot chain lines.

In a light-emitting element 2 according to the second embodiment, the second insulating layer 40 includes the opening 44 as the second opening instead of the opening 41. Furthermore, as illustrated in FIGS. 4 to 6, the first insulating layer 30 includes a plurality of the openings 32 as the first opening instead of the opening 31. The opening 32 penetrates through the first insulating layer 30. The opening 32 is located inside the second extending portion 422 of the third wiring 230 in a plan view. The opening 32 overlaps the region 236 as the second region in a plan view. One opening 32 may be included.

As illustrated in FIGS. 4 and 5, the extending portion 420 of the third wiring 230 includes, as a first region, a region 232 overlapping the n-type semiconductor layer 122 in a plan view. The opening 32 overlaps the region 232 in a plan view. The third wiring 230 may include a plurality of the regions 232.

Apart of the conductive member 20 is disposed inside the opening 32, and the third wiring 230 is in contact with the conductive member 20. That is, the third wiring 230 is electrically connected to the conductive member 20 through the opening 32. On the other hand, the first wiring 210 and the second wiring 220 are not in contact with the conductive member 20.

Other configurations of the second embodiment are basically the same as those of the first embodiment.

In the second embodiment, the third wiring 230 is electrically connected to the conductive member 20 through the opening 32. Thus, a sheet resistance between the second pad electrode 62 and the n-type semiconductor layer 122 can be reduced, and the forward voltage can be reduced. In addition, heat generated in the semiconductor structure 100 is easily transmitted to the conductive member 20, and heat dissipation properties can be improved.

In particular, because the opening 32 overlaps the opening 44 in a plan view, a sheet resistance in the vicinity of the region 236, of the third wiring 230, functioning as a contact region with respect to the n-type semiconductor layer 122 is easily reduced. In addition, since the opening 32 overlaps the region 232 of the third wiring 230 overlapping the n-type semiconductor layer 122 in a plan view, an area of the opening 32 is easily increased, and an area in which the third wiring 230 and the conductive member 20 are in contact with each other is easily increased. Furthermore, since the extending portion 420 of the third wiring 230 includes both the region 232 and the region 236 disposed inside the opening 44, the size of the opening 32 is easily increased, and an area in which the third wiring 230 and the conductive member 20 are in contact with each other is easily increased.

In a plan view, the area of the opening 32 is preferably in a range from 10% to 50% of an area of the second light-emitting unit 120. When the area of the opening 32 is 10% or more of the area of the second light-emitting unit 120, a sheet resistance of the third wiring 230 is easily reduced. When the area of the opening 32 is 50% or less of the area of the second light-emitting unit 120, the area in which the second wiring 220 can be disposed is easily increased.

### Third Embodiment

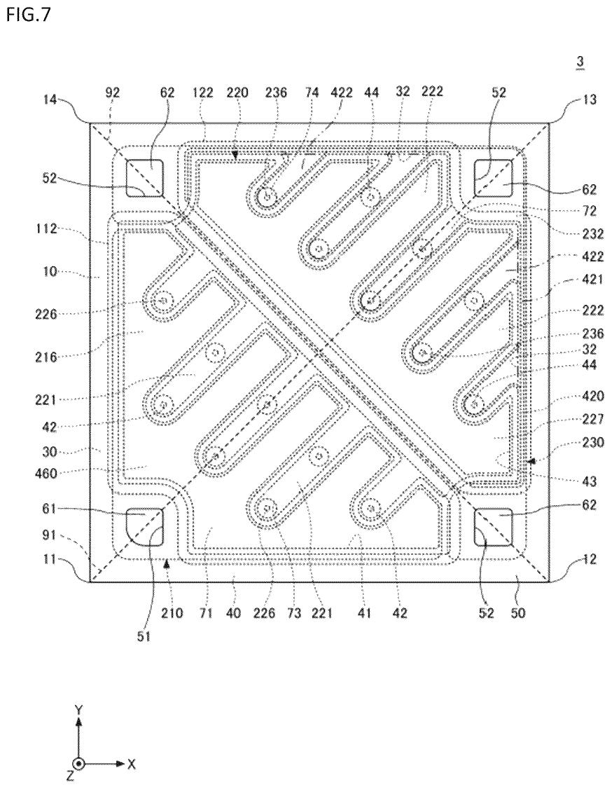

A third embodiment will be described. The third embodiment differs from the second embodiment mainly in a configuration of the opening 32. FIG. 7 is a top view illustrating some of components of a light-emitting element according to the third embodiment.

In a light-emitting element 3 according to the third embodiment, the opening 32 is located overlapping the first extending portion 421 and the second extending portion 422 in a plan view. The opening 32 may further overlap the connection portion 413 in a plan view.

Other configurations of the third embodiment are basically the same as those of the second embodiment.

In the third embodiment, the openings 32 are located in a wider range than in the second embodiment. Thus, the sheet resistance between the second pad electrode 62 and the n-type semiconductor layer 122 can be reduced as compared with the second embodiment, and the forward voltage can be further reduced. In addition, heat dissipation can be further improved.

### Fourth Embodiment

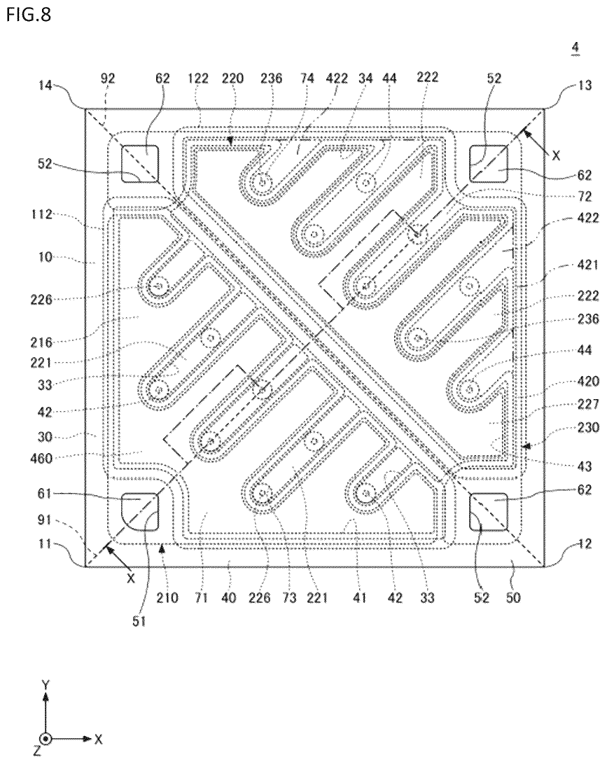

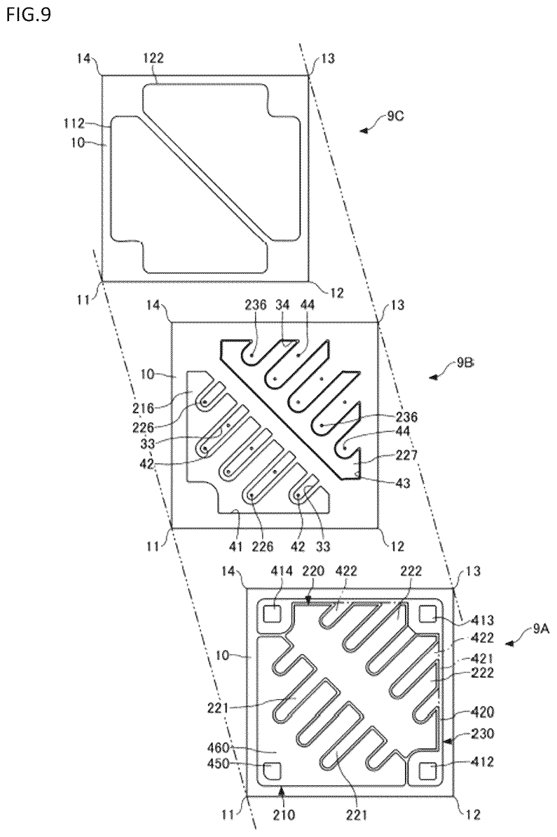

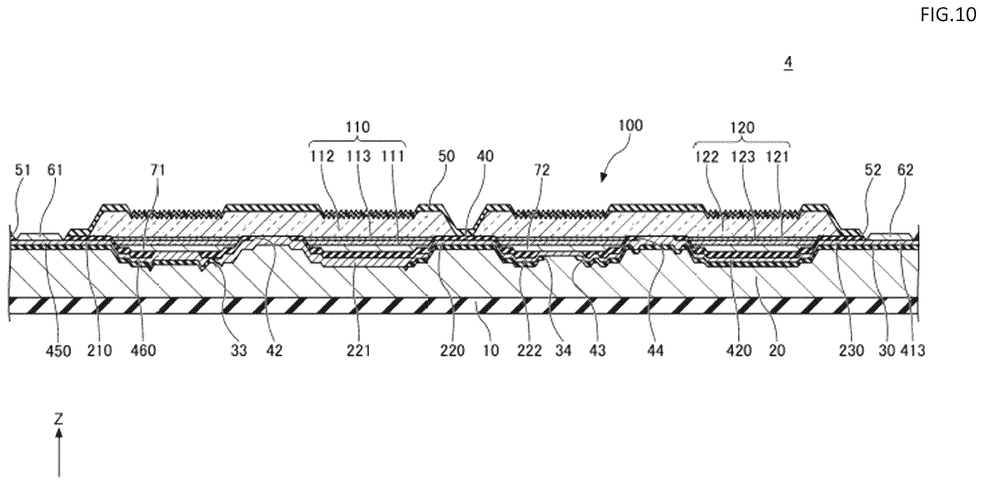

Next, a fourth embodiment will be described. The fourth embodiment differs from the first embodiment mainly in a configuration of the first insulating layer 30. FIG. 8 is a top view illustrating some of components of a light-emitting element according to the fourth embodiment. FIG. 9 is an exploded top view illustrating some of components of the light-emitting element according to the fourth embodiment. FIG. 10 is a cross-sectional view illustrating the light-emitting element according to the fourth embodiment. FIG. 10 corresponds to a cross-sectional view taken along line X-X in FIG. 8.

In a layer 9A in FIG. 9, the arrangement of the first wiring 210, the second wiring 220, and the third wiring 230 is illustrated with respect to the substrate 10. In a layer 9B in FIG. 9, the arrangement of openings 33 and 34 included in the first insulating layer 30, the arrangement of openings 41, 42, 43, and 44 included in the second insulating layer 40, and the arrangement of regions 216, 226, 227, and 236 in the openings 41, 42, 43, and 44 of the first wiring 210, the second wiring 220, and the third wiring 230 are illustrated with respect to the substrate 10. In a layer 9C in FIG. 9 the arrangement of the n-type semiconductor layers 112 and 122 is illustrated with respect to the substrate 10. The two types of vertexes, the vertexes 11 and the vertexes 13, of the substrate 10 are indicated in a manner that the vertexes 11 are connected to each other and the vertexes 13 are connected to each other, between the layers 9A, 9B, and 9C, by respective two-dot chain lines.

In a light-emitting element 4 according to the fourth embodiment, the second insulating layer 40 includes the opening 42 as the second opening instead of the opening 41, and includes the opening 43 as a fourth opening. Furthermore, the first insulating layer 30 includes the opening 33 as the first opening and the opening 34 as the first opening or a third opening, instead of the opening 31. The openings 33 and 34 penetrate through the first insulating layer 30. The opening 33 is located inside the extending portion 221 of the second wiring 220 in a plan view and overlaps at least the opening 42 in a plan view. The opening 34 is located inside the opening 43 in a plan view and overlaps at least the opening 43 in a plan view. The second wiring 220 includes a region 223 overlapping the n-type semiconductor layer 112 in a plan view. The opening 33 overlaps the region 223 as the first region in a plan view. The first insulating layer 30 may include a plurality of the openings 33 or may include a plurality of the openings 34. The second insulating layer 40 may include a plurality of the openings 42. The opening 33 may include a plurality of the regions 223.

Apart of the conductive member 20 is disposed inside the opening 33, another part thereof is disposed inside the opening 34, and the second wiring 220 is in contact with the conductive member 20. That is, the second wiring 220 is electrically connected to the conductive member 20 through the openings 33 and 34. On the other hand, the first wiring 210 and the third wiring 230 are not in contact with the conductive member 20.

Other configurations of the fourth embodiment are basically the same as those of the first embodiment.

In the fourth embodiment, the second wiring 220 is electrically connected to the conductive member 20 through the openings 33 and 34. Thus, a sheet resistance between the n-type semiconductor layer 112 and the p-type semiconductor layer 121 can be reduced, and the forward voltage can be reduced. In addition, heat generated in the semiconductor structure 100 is easily transmitted to the conductive member 20, and heat dissipation properties can be improved.

In particular, because the opening 33 overlaps the opening 42 in a plan view, a sheet resistance in the vicinity of the region 226, of the second wiring 220, functioning as a contact region with respect to the n-type semiconductor layer 112 is easily reduced. Similarly, since the opening 34 overlaps the opening 43 in a plan view, a sheet resistance in the vicinity of the region 227 of the second wiring 220, functioning as a contact region, with respect to the p-type semiconductor layer 121 is easily reduced. In addition, since the opening 33 overlaps the region 223 of the first wiring 210 overlapping the n-type semiconductor layer 112 in a plan view, the opening 33 can be easily formed large, and a large area can be easily obtained in a portion in which the first wiring 210 and the conductive member 20 are in contact with each other.

In a plan view, an area of the opening 33 is preferably in a range from 10% to 50% of the area of the first light-emitting unit 110. When the area of the opening 33 is 10% or more of the area of the first light-emitting unit 110, the sheet resistance of the first wiring 210 is easily reduced. When the area of the opening 33 is 50% or less of the area of the first light-emitting unit 110, the area in which the second wiring 220 can be disposed is easily increased. An area of the opening 34 is preferably in a range from 10% to 50% of the area of the second light-emitting unit 120. When the area of the opening 34 is 10% or more of the area of the second light-emitting unit 120, the sheet resistance of the second wiring 220 is easily reduced. When the area of the opening 34 is 50% or less of the area of the second light-emitting unit 120, the area in which the third wiring 230 can be disposed is easily increased.

### Fifth Embodiment

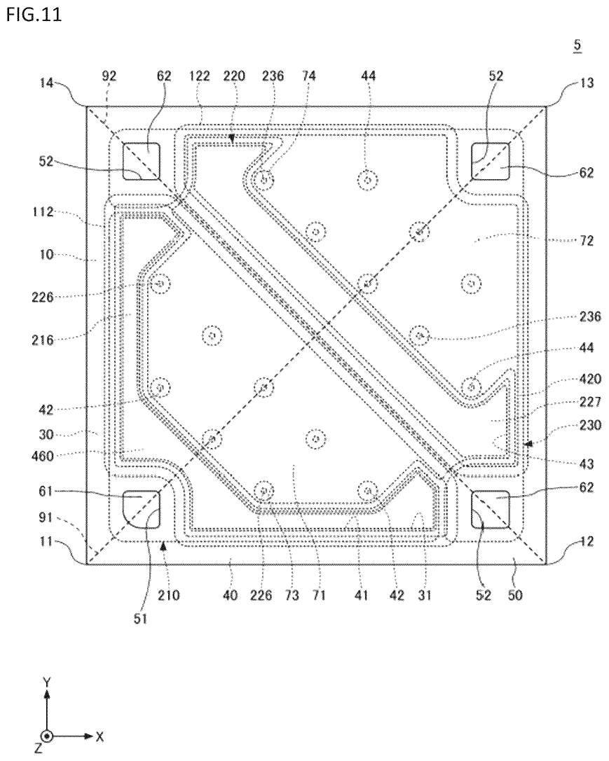

Next, a fifth embodiment will be described. The fifth embodiment differs from the first embodiment mainly in configurations of the first wiring 210, the second wiring 220, and the third wiring 230. FIG. 11 is a top view illustrating some of components of a light-emitting element according to the fifth embodiment.

In a plan view, in the light-emitting element 5 according to the fifth embodiment, the outer shape of the extending portion 460 of the first wiring 210 in a plan view includes a portion parallel to the side connecting the vertexes 11 and 12 to each other and a portion parallel to the side connecting the vertexes 14 and 11 to each other. In a plan view, unlike in the first embodiment, the extending portion 460 does not include the plurality of portions each extending in the direction parallel to the diagonal line 91 connecting the vertexes 11 and 13 to each other. In a plan view, the extending portion 460 has a shape including recessed portions recessed from the diagonal line 92 connecting the vertexes 12 and 14 to each other toward the vertex 11.

The outer shape of the extending portion 420 of the third wiring 230 in a plan view includes a portion parallel to a side connecting the vertexes 12 and 13 to each other, a portion parallel to the diagonal line 92 connecting the vertexes 12 and 14 to each other, and a portion parallel to a side connecting the vertexes 13 and 14 to each other. In a plan view, unlike in the first embodiment, the extending portion 420 does not include the plurality of second extending portions 422. The extending portion 420 extends in the direction parallel to the diagonal line 92 and is electrically connected to the n-type semiconductor layer 122 of the second light-emitting unit 120 through the plurality of openings 44.

In a plan view, unlike in the first embodiment, the second wiring 220 does not include the plurality of extending portions 221. In a plan view, the outer shape of the second wiring 220 includes a portion extending parallel to the diagonal line 92 and is electrically connected to the n-type semiconductor layer 112 of the first light-emitting unit 110 through the plurality of openings 42.

Other configurations of the fifth embodiment are basically the same as those of the first embodiment. The same effect as that of the first embodiment can also be obtained by the fifth embodiment.

In any of the second embodiment, the third embodiment, and the fourth embodiment, the first wiring 210, the second wiring 220, and the third wiring 230 each having the same configuration as that in the fifth embodiment can be used.

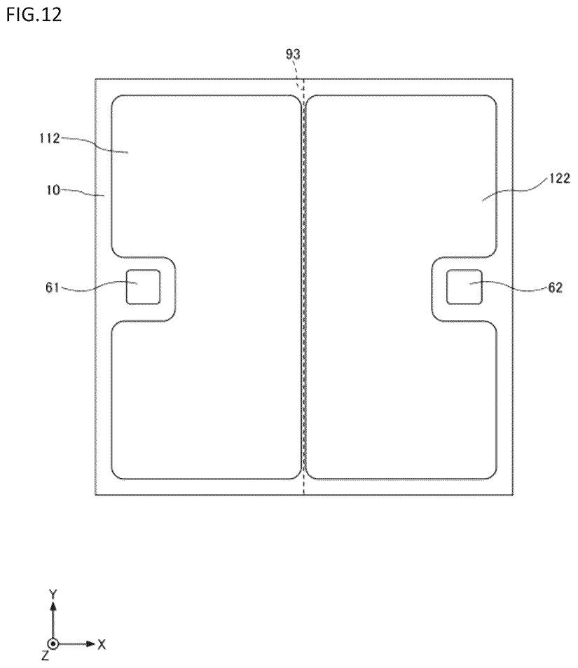

The arrangement of the n-type semiconductor layer, the pad electrode, and the like is not limited to that of any of the above-described embodiments. FIG. 12 is a top view illustrating a modified example of arrangement of an n-type semiconductor layer and a pad electrode.

In the example illustrated in FIG. 12, each of shapes of the n-type semiconductor layers 112 and 122 in a plan view is substantially rectangular. In a plan view, the n-type semiconductor layer 112 is disposed closer to the vertexes 11 and 14 relative to a center line 93 connecting a midpoint of a side connecting the vertex 11 to the vertex 12 and a midpoint of a side connecting the vertex 13 to the vertex 14 to each other, and the n-type semiconductor layer 122 is disposed closer to the vertexes 12 and 13 relative to the center line 93. In a plan view, the first pad electrode 61 is disposed in the vicinity of a midpoint of a side connecting the vertexes 11 and 14 to each other, and the second pad electrode 62 is disposed in the vicinity of a midpoint of a side connecting the vertexes 12 and 13 to each other.

Although not illustrated, the first wiring 210, the second wiring 220, and the third wiring 230, the opening 31 of the first insulating layer 30, and the openings 41, 42, 43, and 44 of the second insulating layer 40 are arranged as in the first embodiment according to the arrangement of the first pad electrode 61, the second pad electrode 62, and the n-type semiconductor layers 112 and 122. Components other than the n-type semiconductor layers 112 and 122 included in the semiconductor structure 100 are also arranged as in the first embodiment according to the arrangement of the first pad electrode 61, the second pad electrode 62, and the n-type semiconductor layers 112 and 122.

The same effect as that of the first embodiment can also be obtained by such a modified example.

### Experimental Example

Next, a test on characteristics of the light-emitting element conducted by the inventors of the present application will be described.

In this test, three samples were prepared according to the first embodiment, the second embodiment, and the fourth embodiment. The shape of the substrate 10 in each sample in a plan view was square, and the length of one side of the substrate 10 was 1000 μm. Then, a current of 500 μmA was caused to flow between the first pad electrode 61 and the second pad electrode 62 of each sample, and the forward voltage and the output were measured. The results are shown in Table 1 below.

TABLE 1

| | FIRST | SECOND | FOURTH |
|---|---|---|---|
| | EMBODIMENT | EMBODIMENT | EMBODIMENT |
| Forward Voltage [V] | 7.96 | 7.84 | 7.88 |
| Output [mW] | 1684 | 1699 | 1681 |

As shown in Table 1, in the sample manufactured according to the second embodiment, the forward voltage was particularly low, and a high output was obtained.

Embodiments of the invention have been described in detail above. However, the invention is not limited to the above-described embodiments, and various modifications and substitutions can be made to the above-described embodiments without departing from the scope of the claims.

What is claimed is:

1. A light-emitting element comprising:
a substrate;
a conductive member disposed on the substrate;
a first insulating layer disposed on the conductive member;
a semiconductor structure comprising a first light-emitting unit and a second light-emitting unit that are spaced apart from each other on the first insulating layer, each of the first light-emitting unit and the second light-emitting unit comprising a first semiconductor layer of a first conductivity type, a second semiconductor layer of a second conductivity type, and a light-emitting layer disposed between the first semiconductor layer and the second semiconductor layer;
a first wiring electrically connected to the first semiconductor layer of the first light-emitting unit;
a second wiring electrically connected to the second semiconductor layer of the first light-emitting unit and the first semiconductor layer of the second light-emitting unit;
a third wiring electrically connected to the second semiconductor layer of the second light-emitting unit;
a first pad electrode separated from the semiconductor structure in a plan view and electrically connected to the first wiring; and
a second pad electrode separated from the semiconductor structure in a plan view and electrically connected to the third wiring, wherein:
the first insulating layer comprises one or more first openings,
the first wiring is in contact with the conductive member through the one or more first openings, and
the second wiring and the third wiring are not in contact with the conductive member.

2. The light-emitting element according to claim 1, further comprising:
a second insulating layer disposed between the first wiring and the first semiconductor layer of the first light-emitting unit, wherein:
the second insulating layer comprises one or more second openings,
the first wiring is electrically connected to the first semiconductor layer of the first light-emitting unit through the one or more second openings, and
the one or more first openings respectively overlap the one or more second openings in a plan view.

3. The light-emitting element according to claim 1, wherein:
a total area of the one or more first openings is in a range from 10% to 50% of an area of the first light-emitting unit in a plan view.

4. A light-emitting element comprising:
a substrate;
a conductive member disposed on the substrate;
a first insulating layer disposed on the conductive member;
a semiconductor structure comprising a first light-emitting unit and a second light-emitting unit that are spaced apart from each other on the first insulating layer, each of the first light-emitting unit and the second light-emitting unit comprising a first semiconductor layer of a first conductivity type, a second semiconductor layer of a second conductivity type, and a light-emitting layer disposed between the first semiconductor layer and the second semiconductor layer;
a first wiring electrically connected to the first semiconductor layer of the first light-emitting unit;
a second wiring electrically connected to the second semiconductor layer of the first light-emitting unit and the first semiconductor layer of the second light-emitting unit;
a third wiring electrically connected to the second semiconductor layer of the second light-emitting unit;
a first pad electrode separated from the semiconductor structure in a plan view and electrically connected to the first wiring; and
a second pad electrode separated from the semiconductor structure in a plan view and electrically connected to the third wiring, wherein
the first insulating layer comprises one or more first openings,
the third wiring is in contact with the conductive member through the one or more first openings, and
the first wiring and the second wiring are not in contact with the conductive member.

5. The light-emitting element according to claim 4, further comprising:
a second insulating layer disposed between the third wiring and the second semiconductor layer of the second light-emitting unit, wherein:
the second insulating layer comprises one or more second openings,
the third wiring is electrically connected to the second semiconductor layer of the second light-emitting unit through the one or more second openings, and
the one or more first openings respectively overlap the one or more second openings in a plan view.

6. The light-emitting element according to claim 5, wherein:
the third wiring comprises one or more first regions overlapping the second semiconductor layer of the second light-emitting unit in a plan view, and
the one or more first openings respectively overlap the one or more first regions in a plan view.

7. The light-emitting element according to claim 6, wherein:
the third wiring comprises:
a connection portion in contact with the second pad electrode, and
one or more extending portions extending from the connection portion in a plan view and electrically connected to the first semiconductor layer of the second light-emitting unit, and
each of the one or more extending portions comprises:
one of the one or more first regions, and
a second region disposed inside a respective one of the one or more second openings.

8. The light-emitting element according to claim 7, wherein:
each of the one or more extending portions comprises:
a first extending portion extending in a direction parallel to an outer edge of the semiconductor structure in a plan view, and
a second extending portion extending from the first extending portion to inside the semiconductor structure in a plan view, and
a respective one of the one or more first openings overlaps the first extending portion and the second extending portion in a plan view.

9. The light-emitting element according to claim 8, wherein, in each of the one or more extending portions, a width of the second extending portion is greater than a width of the first extending portion.

10. The light-emitting element according to claim 4, wherein a total area of the one or more first openings is in a range from 10% to 50% of an area of the second light-emitting unit in a plan view.

11. A light-emitting element comprising:
a substrate;
a conductive member disposed on the substrate;
a first insulating layer disposed on the conductive member;
a semiconductor structure comprising a first light-emitting unit and a second light-emitting unit that are spaced apart from each other on the first insulating layer, each of the first light-emitting unit and the second light-emitting unit comprising a first semiconductor layer of a first conductivity type, a second semiconductor layer of a second conductivity type, and a light-emitting layer disposed between the first semiconductor layer and the second semiconductor layer;
a first wiring electrically connected to the first semiconductor layer of the first light-emitting unit;
a second wiring electrically connected to the second semiconductor layer of the first light-emitting unit and the first semiconductor layer of the second light-emitting unit;
a third wiring electrically connected to the second semiconductor layer of the second light-emitting unit;
a first pad electrode separated from the semiconductor structure in a plan view and electrically connected to the first wiring; and
a second pad electrode separated from the semiconductor structure in a plan view and electrically connected to the third wiring, wherein:
the first insulating layer comprises one or more first openings,
the second wiring is in contact with the conductive member through the one or more first openings, and
the first wiring and the third wiring are not in contact with the conductive member.

12. The light-emitting element according to claim 11, further comprising:
a second insulating layer disposed between the second wiring and the second semiconductor layer of the first light-emitting unit, wherein:
the second insulating layer comprises one or more second openings,
the second wiring is electrically connected to the second semiconductor layer of the first light-emitting unit through the one or more second openings, and
the one or more first openings respectively overlap the one or more second openings in a plan view.

13. The light-emitting element according to claim 12, wherein:
the second wiring comprises one or more first regions overlapping the second semiconductor layer of the first light-emitting unit in a plan view, and
the one or more first openings respectively overlap the one or more first regions in a plan view.

14. The light-emitting element according to claim 12, wherein:
the first insulating layer comprises one or more third openings,
the second insulating layer is also disposed between the second wiring and the first semiconductor layer of the second light-emitting unit,
the second insulating layer comprises one or more fourth openings,
the one or more third openings respectively overlap the one or more fourth openings in a plan view,
the second wiring is electrically connected to the first semiconductor layer of the second light-emitting unit through the one or more fourth openings, and
the second wiring is electrically connected to the conductive member through the one or more third openings.

15. The light-emitting element according to claim 14, wherein a total area of the one or more third openings is in a range from 10% to 50% of an area of the second light-emitting unit in a plan view.

16. The light-emitting element according to claim 11, wherein a total area of the one or more first openings is in a range from 10% to 50% of an area of the first light-emitting unit in a plan view.

17. The light-emitting element according to claim 11, further comprising:
a second insulating layer disposed between the second wiring and the first semiconductor layer of the second light-emitting unit, wherein:
the second insulating layer comprises one or more fourth openings,
the second wiring is electrically connected to the first semiconductor layer of the second light-emitting unit through the one or more fourth openings, and
the one or more first openings respectively overlap the one or more fourth openings in a plan view.

18. The light-emitting element according to claim 17, wherein a total area of the one or more first openings is in a range from 10% to 50% of an area of the second light-emitting unit in a plan view.

19. The light-emitting element according to claim 1, wherein the first insulating layer is disposed between the first pad electrode and the conductive member.

20. The light-emitting element according to claim 4, wherein the first insulating layer is disposed between the first pad electrode and the conductive member.

21. The light-emitting element according to claim 11, wherein the first insulating layer is disposed between the second pad electrode and the conductive member.

22. The light-emitting element according to claim 1, wherein the first insulating layer is disposed between the second pad electrode and the conductive member.

23. The light-emitting element according to claim 4, wherein the first insulating layer is disposed between the second pad electrode and the conductive member.

24. The light-emitting element according to claim 11, wherein the first insulating layer is disposed between the second pad electrode and the conductive member.
